(19) United States
(12) Patent Application Publication
(10) Pub. No.: US 2022/0098729 A1
(43) Pub. Date: Mar. 31, 2022

(54) SYSTEM AND METHOD OF CLEANING PROCESS CHAMBERS USING PLASMA

(71) Applicant: Applied Materials, Inc., Santa Clara, CA (US)

(72) Inventors: Fei WU, Sunnyvale, CA (US); Abdul Aziz KHAJA, San Jose, CA (US); Amit Kumar BANSAL, Milpitas, CA (US); Tuan Anh (Mike) NGUYEN, San Jose, CA (US); Qian SUI, San Jose, CA (US)

(21) Appl. No.: 17/034,937

(22) Filed: Sep. 28, 2020

(51) Int. Cl. C23C 16/44; C23C 16/40; C23C 16/34; C23C 16/455; H01J 37/32

(52) U.S. Cl. CPC C23C 16/4405; C23C 16/401; C23C 16/345; H01J 37/32082; H01J 37/32357; H01J 37/3244; H01J 37/32862; C23C 16/45536

(57) ABSTRACT

The present disclosure relates to a method for cleaning one or more chamber components having contaminants. The method includes introducing a gas mixture to a remote plasma source, the gas mixture includes argon, an oxygen-containing gas and a nitrogen-containing gas. The argon to oxygen gas ratio in the gas mixture is about 0.2:1 to about 1:1 by volume. A plasma is formed from the gas mixture in the remote plasma source. The plasma includes oxygen radicals, argon radicals, and nitrogen radicals. The plasma is introduced to a process volume of the process chamber and exposes surfaces of one or more chamber components. The process volume of the process chamber has a pressure of about 10 mTorr to about 6 Torr and a temperature above 300° C.

### BACKGROUND

### Field

Embodiments of the present disclosure generally relate to systems and methods of manufacturing a semiconductor device. More particularly, the present disclosure is directed to systems and methods of cleaning process chambers using plasma.

### Description of the Related Art

Plasma enhanced chemical vapor deposition (PECVD) are processes used to deposit a film on a substrate, such as a semiconductor substrate. PECVD is accomplished by introducing process gasses into a process chamber that contains the substrate. The process gasses are directed through a gas distribution assembly and into a process volume in the process chamber.

Electromagnetic energy, such as from radio frequency (RF) power is used to activate the process gasses in the process chamber to generate plasma. The plasma is used to for a variety of processes including etching, thin film deposition in semiconductor substrates, and chamber cleaning. Plasma processes vary greatly and depend on temperature, pressure, type of gas, gas flow rate, and other process conditions. Moreover, plasma cleaning varies in efficiency, effectiveness, and damage to chamber components.

Therefore, there is a need for an efficient, effective chamber clean method and system with minimal damage to chamber components.

### SUMMARY

In one embodiment, a method is provided including introducing a gas mixture to a remote plasma source, the gas mixture includes argon, oxygen and nitrogen gas. The argon gas to oxygen gas ratio in the gas mixture is about 0.2:1 to about 1:1 by volume. A plasma is formed from the gas mixture in the remote plasma source. The plasma includes oxygen radicals, argon radicals, and nitrogen radicals. The plasma is introduced to a process volume of the process chamber and exposes surfaces of one or more chamber components. The process volume of the chamber has a pressure of about 10 mTorr to about 6 Torr and a temperature above 300° C.

In another embodiment, a method is provided, including introducing a gas mixture having argon gas, nitrogen gas, and oxygen gas to a remote plasma source. The gas mixture has a nitrogen gas to oxygen gas ratio of between about 1:1000 to about 1:5 by volume. The gas mixture is energized in the remote plasma source to form a plasma. The plasma is composed of oxygen radicals, argon radicals, and nitrogen radicals. The plasma is introduced to a process volume of the process chamber. The process chamber includes a chamber body and a lid defining a volume of the process chamber. A substrate support disposed in the volume of the process chamber, and a faceplate is disposed between the substrate support and the lid. A blocker plate or a flange is disposed between the faceplate and the lid. The blocker plate includes perforations dispose throughout the surface of the blocker platen and the perforations have a uniform diameter of about 0.1 mm to about 2 mm. The method includes exposing the faceplate within the process volume to the plasma.

In another embodiment, a method is provided including coating a portion of a chamber component. The coating is selected from the group consisting of a metal oxide, a metal nitride, a silicon containing composition, and combination(s) thereof. The chamber component is processed using processing conditions during substrate processing. Contaminants are formed on the chamber component. The chamber component is exposed to a cleaning plasma including oxygen radicals, argon radicals, and nitrogen radicals. The plasma is formed from a gas mixture having an argon gas to oxygen gas ratio of about 0.2:1 to about 1:1 by volume and a nitrogen gas to oxygen gas ratio of between about 1:1000 to about 1:5 by volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only example embodiments of this disclosure and are therefore not to be considered limiting of its scope, for the disclosure may admit to other equally effective embodiments.

FIG. 1A depicts a schematic view of a processing chamber according to an embodiment of the present disclosure.

FIG. 1B depicts a schematic view of the processing chamber with a blocker plate according to an embodiment of the present disclosure.

FIG. 2 depicts a bottom view of a faceplate according to an embodiment of the present disclosure.

FIG. 3 depicts a bottom view of a blocker plate according to an embodiment of the present disclosure.

FIG. 4 depicts a flow diagram of a cleaning method according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments presented herein are directed to plasma cleaning in process chambers. The plasma cleaning described herein is useful to efficiently clean contaminants such as carbon based contaminants from chamber components, such as faceplates.

Methods of cleaning process chamber components is provided herein including forming a plasma composed of oxygen radicals, argon radicals, and nitrogen radicals. The plasma is formed in a remote plasma source and is introduced to a process volume of the process chamber and exposes one or more chamber components disposed therein for cleaning.

The process chamber includes a blocker plate or a flange, and a faceplate disposed between a lid and a substrate support of the chamber. The blocker plate and faceplate are designed to manage plasma flow distribution into a process volume of the process chamber.

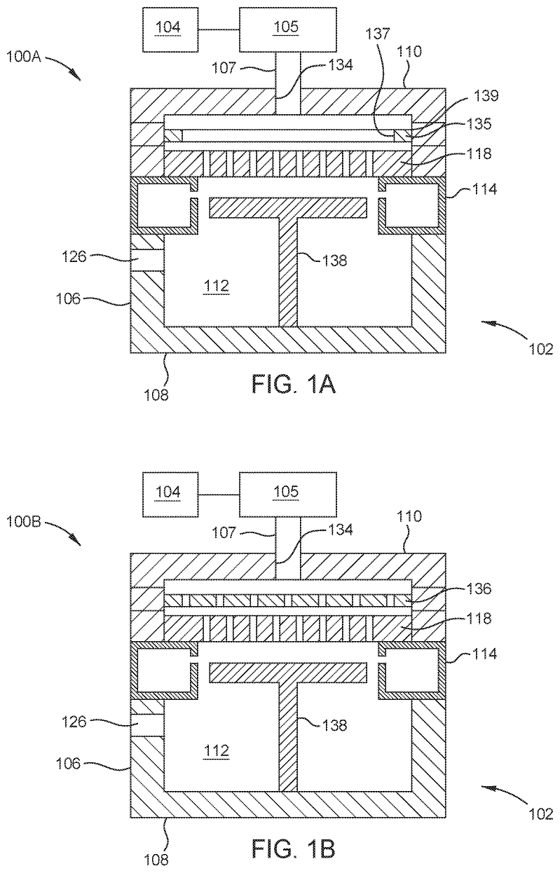

FIG. 1A depicts a schematic view of the process chamber 100A according to an embodiment of the present disclosure. The process chamber 100A includes a chamber body 102 and a lid 110 disposed on the chamber body 102. The chamber body 102 includes sidewalls 106, a bottom 108, and the lid 110, defining a process volume 112. The lid 110 is coupled to a faceplate 118 with a plurality of holes formed therethrough for supplying a plasma from a remote plasma source 105, which is coupled to the lid 110 via a remote plasma source extension 107, to the process volume 112. A gas source 104 is coupled to the remote plasma source 105 to supply gas to the remote plasma source 105. The sidewalls 106 and the bottom 108 are fabricated from a unitary block, such as a block of metal, such as aluminum. The chamber body 102 includes an exhaust manifold 114 that facilitates of pumping components and controlling the pressure within the process volume 112. The pumping manifold 114 is coupled to a vacuum pump (not shown).

The faceplate 118 is coupled to a portion of the lid assembly 110 and is coupled to a power supply (not shown), such as radiofrequency (RF) power for facilitating plasma generation within the processing chamber 100A. A gas feedthrough 134 is disposed in the lid 110 and is coupled to the remote plasma source 105, such that process gases are introduced to the process volume 112 by passing through the feedthrough 134 and faceplate 118. During chamber cleaning processes, cleaning gases are supplied from one or more gas sources (e.g., 104) to the remote plasma source 105, and distributed by the faceplate 118. In some embodiments, which can be combined with other embodiments described herein, the faceplate 118 is designed to distribute gas into the process volume 112 with a predetermined gas distribution profile.

A substrate support assembly 138 is disposed below the faceplate 118. A substrate is positionable on the substrate support assembly 138 through a port 126 in the sidewalls 106. During processing, a substrate is secured to the substrate support assembly 138 by vacuum or by electrostatic chuck. The temperature of the substrate is increased to a process temperature by heating the substrate support assembly 138 with a heater (not shown).

A flange 135 is removably coupled to the process chamber between the lid 110 and the faceplate 118, as shown in FIG. 1A. The flange 135 and the faceplate 118 are part of a gas distribution assembly (e.g., stack), formed from a plurality of separable plates, as shown in FIGS. 1A, 1B. The flange 135 is positioned within the gas distribution assembly to enable the faceplate 118 to be spaced away from the lid 110, and is used as a placeholder for a perforated blocker plate 136 as shown in FIG. 1B. The flange 135 includes an inner flange radius 137 and an outer flange radius 139. The outer flange radius 139 corresponds to the outer radius of the blocker plate 136 as shown in FIG. 1B. The plasma and/or gas supplied from the remote plasma source 105 is provided directly to the faceplate 118. Alternatively, the flange 135 is removed and replaced with the perforated blocker plate 136.

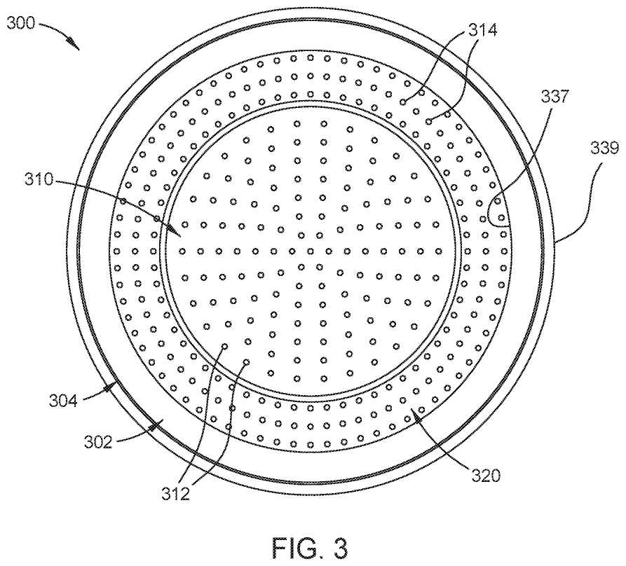

FIG. 1B depicts a process chamber 100B with the perforated blocker plate 136 disposed between the faceplate 118 and the gas feedthrough 134. The blocker plate 136 is disposed in a location similar to the flange 135 as described with reference to FIG. 1A. The blocker plate 136 has an inner blocker plate radius (e.g., radius 337 shown in FIG. 3) and outer blocker plate radius (e.g., radius 339 shown in FIG. 3). The inner blocker plate radius 337 is similar to the inner flange radius 137 and the outer flange radius 139 is similar to the outer blocker plate radius 339.

The blocker plate 136 is positioned and configured to enhance the uniform distribution of gases passing through the faceplate 118 and into the chamber volume 112. In both arrangements described in FIG. 1A and FIG. 1B, an increase in radical flux conductance from the remote plasma source radical outlet through the blocker plate 136 or flange 135, and faceplate 118 to the process volume 112 is achieved. The increase in radical flux is due to absence of a blocker plate 136 as shown FIG. 1A, or a blocker plate with hole diameter size and hole density as described herein. The increased radical flux results in improved cleaning. In some embodiments, which can be combined with other embodiments described herein, a blocker plate 136 is used during deposition of films over a substrate and is removed and replaced with a flange 135 during cleaning operations described herein. In some embodiments, which can be combined with other embodiments described herein, a first blocker plate having a first set of perforations disposed therethrough is used during deposition of films over a substrate and is removed and replaced with a second blocker plate having a second set of perforations disposed therethrough during cleaning operations described herein. The second set of perforations have a larger diameter than the first set of perforations to increase radical conductance for plasma cleaning.

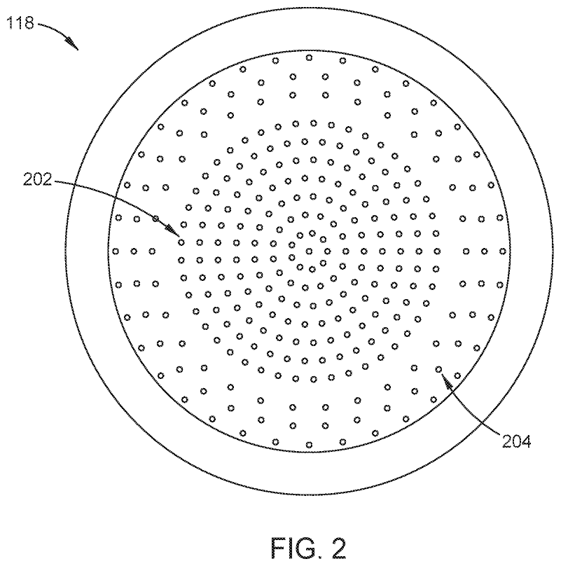

FIG. 2 depicts an example faceplate 118 in accordance with some aspects of the present disclosure. The faceplate 118 includes a central region 202 and an edge region 204. The edge region 204 is concentric with the central region 202. Each of the central region 202 and the edge region 204 includes perforations that facilitates passage of gases therethrough. In some embodiments, which can be combined with other embodiments described herein, the central region 202 has a uniform hole density. In some embodiments, which can be combined with other embodiments described herein, the perforation hole sizes of the faceplate 118 are uniform throughout the faceplate 118. As used herein, the term “hole density” refers to a number of perforations per surface area of a reference region (e.g., central region 202, edge region 204). In some embodiments, which can be combined with other embodiments described herein, a hole spacing, defined by the distance from a center of a first hole and a center of a second adjacent hole, is about 0.8 mm to about 4 mm. In some embodiments, which can be combined with other embodiments described herein, a diameter of each perforation of the faceplate 118 is about 1.5 mm to about 5 mm, such as about 2 mm to about 3 mm. The faceplate 118 includes perforations having large diameters to increase cleaning plasma flow through the faceplate 118.

In one example, a central hole density of the central region 202 is the same as an edge hole density of the edge region 204, or the central hole density of the central region 202 is greater than the edge hole density of the edge region 204, or the central hole density of the central region 202 is less than the edge hole density of the edge region 204. For example, the central hole density of the central region 202 is greater than the edge hole density of the edge region 204 to increase the gas flow through the central region 202 relative to the edge region 204. In some embodiments, which can be combined with other embodiments described herein, the edge hole density is about 20% to about 60% lower than the central hole density. The edge hole density is uniform throughout the edge region 204, or the edge hole density is reduced radially outward from the center of the faceplate 118.

The central region 202 is sized based on the size of a substrate processed within the process volume. For example, the central region 202 may be about 200 millimeters (mm) to about 450 mm in diameter, such as about 200 mm, 300 mm, 320 mm or 450 mm in diameter. Other diameters are also contemplated. The edge region 204 has an outer edge diameter about 5% to about 25% larger than the diameter of the central region 202. The faceplate 118 described herein, has a faceplate design that distributes radical flux uniformly through the faceplate 118 to the process volume. The faceplate design includes geometry of the perforation holes (e.g., large hole size) and hole density (e.g., high hole density) over the different regions of the faceplate 118. The faceplate design includes holes arranged in a concentric pattern.

FIG. 3 depicts an example blocker plate 136 in accordance with some embodiments described herein. The blocker plate 136 is a circular body that includes an inner region 310, an outer region 320, a flange portion 302 disposed at the periphery of the circular body, and a seal 304, such as an O-ring embedded in the flange 302. The seal 304 facilitates formation of a seal when the blocker plate 136 is installed in a process chamber. The inner region 310 includes perforations 312 spaced throughout the inner region 310 having an inner hole density. The blocker plate 136 includes an outer region 320 with outer perforations 314 distributed throughout the outer region 320 having an outer hole density. The blocker plate 136 is configured to enable a predetermined gas flow distribution to the faceplate 118, such as an increased gas flow in the edge region 204 of the faceplate 118. The hole density of blocker plate 136 can be uniform for both inner region 310 and outer region 320. In an example cleaning process, such as the cleaning process described herein, a blocker plate 136 having an outer region hole density about 5 percent to about 25 percent, such as about 10 percent to about 20 percent higher than an inner region hole density is used to enhance cleaning plasma flow through the outer region 320 of the blocker plate 136. In some embodiments, which can be combined with other embodiments described herein, a diameter of each perforation (e.g., 312, 314) of the blocker plate 136 is about 0.1 mm to about 2 mm, such as about 1 mm to about 2 mm. The blocker plate 136 includes perforations (e.g., 312, 314) having large diameters to increase cleaning plasma flow through the blocker plate 136. In some embodiments which can be combined with other embodiments described herein, the inner region 310 has a first diameter of about 300 mm to about 320 mm, and the outer region 320 has a second diameter of about 320 mm to about 360 mm. The inner region 310 of the blocker plate 136 corresponds to the central region 202 of the faceplate 118 and the outer region 320 of the blocker plate 136 corresponds to the edge region 204 of the faceplate 118. In some embodiments, which can be combined with other embodiments disclosed herein, the inner region 310 of the blocker plate 136 is about 0 to about 10%, such as about 1% to about 5% larger than the central region 202 of the faceplate 118. A high hole density in the outer region 320 of the blocker plate 136 enhances the cleaning of the edge region 204 of the faceplate 118.

The blocker plate 136 described herein distributes radical flux uniformly through the blocker plate 136 to the process volume 112. The geometry of the perforation holes (e.g., hole size) and hole density over the different regions of the blocker plate 136 facilitates the increased radical flux uniformity. The blocker plate 136 and the faceplate 118, or the flange 135 and faceplate 118, have high radical conductance and high etch efficiency in the chamber volume 112. In some embodiments, which can be combined with other embodiments described herein, each hole diameter is about 0.1 mm to about 3 mm, such as about 0.3 mm to about 2 mm. In some embodiments, which can be combined with other embodiments described herein, a hole spacing, defined by the distance from a center of a first hole and a center of a second adjacent hole, is about 2 mm to about 15 mm for the blocker plate 136.

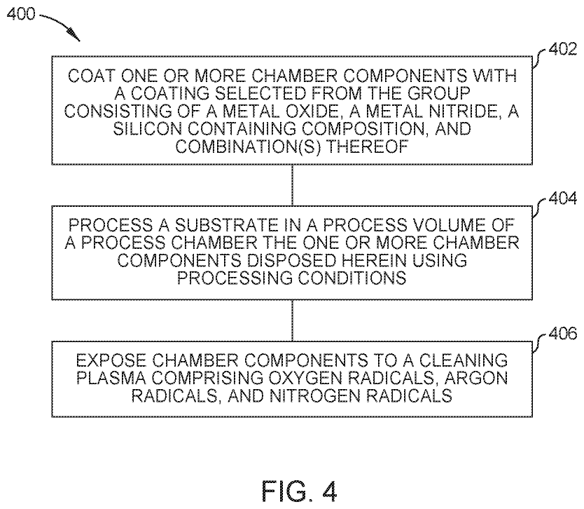

FIG. 4 depicts a flow diagram of a cleaning method 400 according to an example embodiment of the present disclosure. In operation 402, at least one of the chamber components is coated with a coating. The coating is one or more of a metal oxide, a metal nitride, and a silicon containing composition, such as silicon oxide. The chamber components coated in operation 402 are one or more of a faceplate, a heater surface, a remote plasma source extension 107, a pedestal, heater, a blocker plate, and chamber walls, such as all components disposed within the chamber. In some embodiments, which can be combined with other embodiments described herein, one or more surface of each component is coated, such as a back side surface of the faceplate and/or the front side surface of the faceplate. Without being bound by theory, it is believed that each surface of each chamber component shows evidence of different levels of radical recombination during cleaning. Coating can be applied to all surfaces or selectively based on a level of risk of damaging a particular surface using a recombination assessment. The recombination assessment includes an on-substrate clean rate test, such as an etch rate, at predetermined cleaning conditions. The coating protects the underlying surface during substrate processing and further during cleaning processes.

At least one of the chamber components is coated with a film having a film thickness of about 100 nm to about 3 um and an average surface roughness of less than Ra 64, such as less than Ra 20, as determined by atomic force microscopy. The one or more chamber components are coated by physical vapor deposition (PVD), atom layer deposition (ALD), plasma spray, and electron beam and ion beam assisted deposition (EB-IAD), chemical vapor deposition (CVD), or any other method of deposition capable of depositing the coating. In some embodiments, which can be combined with other embodiments described herein, the coating is aluminum oxide deposited by ALD, yttrium oxide (e.g., yttria) deposited by ALD, yttrium doped with silicon oxide deposited by ALD, aluminum oxide doped with silicon oxide deposited by ALD, yttrium oxyfluoride (e.g., YOF) deposited by ALD, hafnium oxide (HfO₂) deposited by ALD, aluminum oxide deposited by EB-IAD, yttrium oxide zirconium oxide (e.g., Y₂O₃-ZrO₂) deposited by EB-IAD, yttrium aluminum garnet (YAG) deposited by EB-IAD, and combination(s) thereof. The coating is deposited over the chamber component ex situ, for example using ALD and/or by EB-IAD. Alternatively or additionally, the coating is deposited in situ, and may include silicon oxide, silicon nitride, silicon carbide, silicon carbon nitride (SiCN), carbon, deposited by CVD. Any high quality coating composition can be used and deposited by any method and any coating described herein can be doped with silicon oxide (SiOx). A high quality coating refers to a film having uniform stoichiometry of composition molecules, high purity, high density, no (or minimal) hydroxides or carbon hydroxide groups. In some embodiments, which can be combined with other embodiments described herein, the coating process is performed in the same chamber as the cleaning process. In such an example, the coating process may be a seasoning process. In some embodiments, which can be combined with other embodiments described herein, the coating process is performed in a different chamber as the cleaning process.

The coating deposited thereon has an average surface roughness value less than 16 Ra, as determined by atomic force microscopy (AFM). It is believed that having a low average surface roughness reduces surface recombination of radicals upon exposure to radicals. The coated chamber component enables better etch rate when compared to uncoated chamber components. Moreover, coated chamber components are less susceptible to damage from the process chemistry than uncoated chamber components.

Referring back to FIG. 4, in operation 404, a deposition process, such as chemical vapor deposition of film over a substrate, is performed. As a result of the deposition process, material (e.g., contaminants) is also deposited on chamber components within the process chamber. In some embodiments, which can be combined with other embodiments described herein, carbon film is deposited over the substrate and amorphous carbon contaminants are deposited onto one or more chamber components. While carbon films are provided as one example, it is contemplated that other films, and other deposition techniques, as well as other processes, such as etching, may be utilized, resulting in various contaminants. Example deposition techniques include plasma enhanced chemical vapor deposition, atomic layer deposition, electron beam and ion assisted deposition (EB-IAD), and combination(s) thereof. In some embodiments, which can be combined with other embodiments described herein, the deposition process of operation 404 is in the same chamber as the coating process of operation 402. Alternatively, the deposition process of operation 404 is a different chamber as the coating process of operation 402.

In operation 406, the one or more chamber components having amorphous carbon, and/or semiconductor contaminants are exposed to a cleaning plasma, within a process chamber. In some embodiments, which can be combined with other embodiments described herein, the process chamber of operation 406 is the same chamber as chambers of operation 402 and/or operation 404. The cleaning plasma includes oxygen radicals, argon radicals, and nitrogen radicals. Oxygen-radical-containing plasma is effective for cleaning contaminants such as amorphous carbon. The plasma is formed by providing oxygen-containing gas from a gas source 104 to the remote plasma source 105. The oxygen-containing gas, such as oxygen gas (O₂) is introduced to the remote plasma source 105 to form neutral radical species in the remote plasma source 105. Additionally, one or more of nitrogen-containing gas and argon gas are also provided to the remote plasma source, and generated neutral and active radical species. The nitrogen-containing gas includes one or more of N₂, N₂O, NO, and combinations thereof. Although FIGS. 1A and 1B only show a single gas source 104, it is also contemplated that multiple gas sources 104 may be included to supply each gas from different gas sources. In some embodiments, which can be combined with other embodiments disclosed herein, the oxygen-containing gas, such as O₂, is introduced to the RPS at about 6000 sccm to about 20000 sccm, the argon gas is introduced to the RPS at about 4000 sccm to about 10000 sccm, and the nitrogen-containing gas, such as N₂, is introduced to the RPS at about 20 sccm to about 2000 sccm. The gas mixture delivered to the RPS includes an Ar to O₂ ratio of about 0.2:1 to about 1:1 by volume. Additionally, or alternatively, the gas mixture includes an N₂ gas to O₂ gas ratio of about 1:1000 to about 1:5 by volume. Without being bound by theory, it is believed that the radicals generated by the remote plasma actively react with contaminants to remove the contaminants from the chamber components.

The gas mixture is energized in the remote plasma source 105 using an excitation source to form a plasma. In some embodiments, which can be combined with other embodiments described herein, the excitation source is radiofrequency, microwave, or combinations thereof. The gas mixture is energized at a power of about 7000 W to about 10000 W, such as about 8000 W to about 9000 W.

During excitation, each of the gas components of the gas mixture are dissociated to radicals in the remote plasma source 105 to form a plasma. One or more chamber components are exposed to the plasma for about 80 seconds to about 600 seconds, such as about 100 seconds to about 400 seconds, such as about 100 seconds to about 200 seconds for cleaning. The plasma flow rate is about 10,000 sccm to about 32,000 sccm, such as about 15,000 sccm to about 25,000 sccm. The oxygen radicals facilitate effective cleaning of process chamber components when the oxygen radicals are present in a high oxygen radical density. In some embodiments, which can be combined with other embodiments described herein, the percentage of oxygen gas converted to oxygen radicals is about 20 to about 30 percent. The percentage is characterized by the number of molecules per unit of volume. Without being bound by theory, it is believed that argon radicals combined with oxygen containing gas promotes oxygen dissociation and oxygen radical generation. Another consideration is that the oxygen atoms have a tendency to recombine by the time the oxygen reaches certain chamber surfaces. Combining oxygen radicals, argon radicals, and a nitrogen radicals as described herein increases the oxygen radical density and lifetime (e.g., reduce oxygen radical recombination), thus improving cleaning of process chamber components. The combination of gases as described herein showed improved (e.g., reduced) etch times when compared with other types of cleaning such as in situ radiofrequency cleaning.

The RPS cleaning of the present disclosure cleans films on chamber component surfaces having a film thickness about 4 microns to 6 microns in about 100 seconds to about 200 seconds, such as about 130 seconds to about 170 seconds, such as about 150 seconds. The RPS cleaning of the present disclosure is capable of removing contaminants at an etch rate (ER) of about 10000 angstroms/min to about 80000 angstroms/min, such as about 20000 angstroms/min to about 60000 angstroms/min.

Moreover, the RPS cleaning process described herein exhibits limited ion bombardment and sputtering of etched material onto chamber components when compared to other cleaning methods, such as RF cleaning. Limiting ion bombardment and sputtering reduces damage to the component parts. It has also been discovered that a pressure of the process volume affects clean etch efficiency. In particular, a chamber pressure of about 10 mtorr to about 6 torr, such as about 1 torr to about 4 torr, results in the highest etch efficiency. Without being bound by theory, as pressure exceeds a certain pressure range, collision between radicals is increased, which increases radical recombination, and thus reduces etch rate efficiency. Moreover, if the pressure is below a certain pressure range, the low density of radicals results in radicals not being effectively delivered to the reaction volume. In some embodiments, which can be combined with other embodiments described herein, a process temperature (e.g., substrate temperature) is greater than about 300° C., such as greater than about 600° C.

In summation, method for cleaning one or more chamber components having contaminants is provided. The method includes introducing a gas mixture to a remote plasma source, the gas mixture includes argon, oxygen (or any oxygen-containing gas) and nitrogen (or any nitrogen-containing) gas. A plasma is formed from the gas mixture in the remote plasma source and introduced to a chamber, exposing chamber components to the cleaning plasma. The cleaning plasma has high cleaning efficiency and reduced tendency to damage chamber component surfaces.

Certain features, structures, compositions, materials, or characteristics described herein is combined in any suitable manner in one or more embodiments. Although the present disclosure herein has been described with reference to particular embodiments, it is to be understood that these embodiments are merely illustrative of the principles and applications of the present disclosure. It will be apparent to those skilled in the art that various modifications and variations can be made to the method and systems of the present disclosure. Thus it is intended that the present disclosure include modifications and variations that are within the scope of the appended claims and their equivalents.

1. A method of cleaning comprising:
introducing a gas mixture in a remote plasma source, the gas mixture comprising argon gas, nitrogen-containing gas, and oxygen gas, the gas mixture comprising an argon gas to oxygen gas ratio of about 0.2:1 to about 1:1 by volume;
forming a plasma in the remote plasma source, the plasma comprising oxygen radicals, argon radicals, and nitrogen radicals formed from the gas mixture;
introducing the plasma to a process volume of a process chamber; and
and exposing one or more chamber components to the plasma, the process volume comprising a pressure of about 10 mTorr to about 6 Torr and a temperature above 300° C.

2. The method of claim 1, wherein the nitrogen gas is selected from the group consisting of NO, N₂, N₂O, and combinations thereof.

3. The method of claim 2, wherein the nitrogen gas comprises N₂, and the gas mixture comprises an N₂ gas to oxygen gas ratio of about 1:1000 to about 1:5 by volume.

4. The method of claim 1, further comprising energizing the gas mixture using an excitation source at a power of about 7000 W to about 10000 W, wherein the excitation source is a remote radiofrequency (RF) power source.

5. The method of claim 1, further comprising removing contaminants disposed on the chamber components, wherein the contaminants comprise amorphous carbon or a semiconducting material.

6. The method of claim 1, wherein the one or more of the chamber components is selected from the group consisting of a faceplate, a heater surface, an remote plasma source extension, a pedestal, a blocker plate, chamber walls, and combination(s) thereof.

7. The method of claim 1, wherein introducing the gas mixture to the remote plasma source comprises, introducing oxygen gas at about 6000 sccm to about 200000 sccm; introducing argon gas at about 4000 sccm to about 10000 sccm; and introducing the nitrogen gas at about 20 sccm to about 2000 sccm.

8. The method of claim 1, wherein exposing one or more chamber components comprises exposing one or more chamber components to the plasma for about 100 seconds to about 200 seconds.

9. A method of cleaning comprising:
introducing a gas mixture comprising argon gas, nitrogen gas, and oxygen gas to a remote plasma source, the gas mixture comprising a nitrogen gas to oxygen gas ratio of between about 1:1000 to about 1:5 by volume;
energizing the gas mixture to form a plasma comprising oxygen radicals, argon radicals, and nitrogen radicals;
introducing the plasma to a process volume of a process chamber, the process chamber comprising:
a chamber body and a lid defining a volume of the process chamber,
a substrate support disposed in the volume of the process chamber,
a faceplate disposed between the substrate support and the lid, and
a blocker plate disposed between the faceplate and the lid, the blocker plate comprising a plurality of perforations, each perforation having a diameter of about 0.1 mm to about 2 mm; and
exposing the faceplate within the process volume to the plasma.

10. The method of claim 9, wherein the blocker plate comprises a first hole density on an outer region of the blocker plate and a second hole density on an inner region of the blocker plate, wherein the first hole density is 20 percent (%) higher than the second hole density.

11. The method of claim 10, wherein the inner region of the blocker plate comprises a first radius of about 150 mm to about 160 mm, and the outer region of the blocker plate comprises a second radius of about 160 mm to about 180 mm.

12. The method of claim 9, further comprising removing residue disposed on the faceplate, wherein the residue comprises amorphous carbon.

13. The method of claim 9, further comprising coating the faceplate with a coating comprising silicon oxide, silicon nitride, silicon carbide, or combinations thereof by plasma enhanced chemical vapor deposition.

14. The method of claim 9, further comprising coating the faceplate with a film comprising a film thickness of about 100 nm to about 3 um and an average surface roughness of less than 16 Ra, as determined by atomic force microscopy.

15. A method comprising:
coating a portion of a chamber component with a coating selected from the group consisting of a metal oxide, a metal nitride, a silicon containing composition, and combination(s) thereof;
processing the chamber component using processing conditions; and
exposing the portion of chamber component to a plasma comprising oxygen radicals, argon radicals, and nitrogen radicals, wherein the plasma is formed from a gas mixture comprising an argon gas to oxygen gas ratio of about 0.2:1 to about 1:1 by volume and a nitrogen gas to oxygen gas ratio of between about 1:1000 to about 1:5 by volume.

16. The method of claim 15, wherein the coating is deposited by plasma enhanced chemical vapor deposition, atomic layer deposition, electron beam and ion assisted deposition (EB-IAD), and combination(s) thereof.

17. The method of claim 15, wherein the chamber component is composed of aluminum, stainless steel, nickel, alloys thereof, or combinations thereof.

18. The method of claim 15, wherein the chamber component is selected from the group consisting of a faceplate, a heater surface, an remote plasma source extension, a pedestal, a blocker plate, chamber walls, and combination(s) thereof.

19. The method of claim 15, wherein exposing the chamber component to the plasma further comprises introducing the plasma to a process volume comprising a pressure of about 10 mTorr to about 6 Torr.

20. A system comprising an algorithm stored in a memory of the system, wherein the algorithm comprises instructions which, when executed by a processor, causes the method of claim 14 to be performed.
